(19) United States
(12) Patent Application Publication
(10) Pub. No.: US 2022/0048155 A1
(43) Pub. Date: Feb. 17, 2022

(54) POLISHING APPARATUS AND POLISHING METHOD

(71) Applicant: Kioxia Corporation, Tokyo (JP)

(72) Inventors: Mikiya SAKASHITA, Nagoya Aichi (JP); Akifumi GAWASE, Kuwana Mie (JP); Kohei NAKAMURA, Yokkaichi Mie (JP); Yukiteru MATSUI, Nagoya Aichi (JP)

(73) Assignee: Kioxia Corporation, Tokyo (JP)

(21) Appl. No.: 17/184,860

(22) Filed: Feb. 25, 2021

(30) Foreign Application Priority Data
Aug. 17, 2020 (JP) 2020-137589

(51) Int. Cl. B24B 37/10; B24B 37/30; B24B 37/20; B24B 47/10; B24B 49/04; B24B 37/005

(52) U.S. Cl. CPC B24B 37/105; B24B 37/30; B24B 37/005; B24B 47/10; B24B 49/04; B24B 37/20

(57) ABSTRACT

A polishing apparatus includes a first substrate holder capable of holding a substrate coated with a film. The apparatus also includes a first pad holder capable of holding a first pad. The apparatus further includes a first driver configured to translate the first pad on a surface of the film so as to cause the first pad to polish the film.

### CROSS-REFERENCE TO RELATED APPLICATION

This application is based upon and claims the benefit of priority from Japanese Patent Application No. 2020-137589, filed Aug. 17, 2020, the entire contents of which are incorporated herein by reference.

### FIELD

Embodiments described herein relate generally to a polishing apparatus and a polishing method.

### BACKGROUND

When a film coated on a substrate is polished and planarized, it is desirable that a film thickness of this film can be appropriately corrected.

### DESCRIPTION OF THE DRAWINGS

FIG. 1 is a plan view of a polishing apparatus according to a first embodiment, illustrating a configuration thereof.

FIG. 2 is a perspective view of a polisher according to the first embodiment, illustrating a configuration thereof.

FIG. 3 is a perspective view of a polisher according to the first embodiment, illustrating a configuration thereof.

FIGS. 4A to 4C are plan views illustrating the polisher according to the first embodiment more specifically.

FIGS. 5A to 5C are cross-sectional views illustrating a configuration and operation of the polisher according to a second embodiment.

FIGS. 6A to 6D are cross-sectional views illustrating a configuration and operation of the polisher according to a third embodiment.

FIGS. 7A to 7D are cross-sectional views illustrating a configuration and operation of the polisher according to a fourth embodiment.

### DETAILED DESCRIPTION

At least one embodiment provides a polishing apparatus and a polishing method that enable appropriate correction of a film thickness of a film coated on a substrate.

In general, according to at least one embodiment, a polishing apparatus includes a first substrate holder capable of holding a substrate coated with a film. The apparatus also includes a first pad holder capable of holding a first pad. The apparatus further includes a first driver configured to translate the first pad on a surface of the film so as to cause the first pad to polish the film.

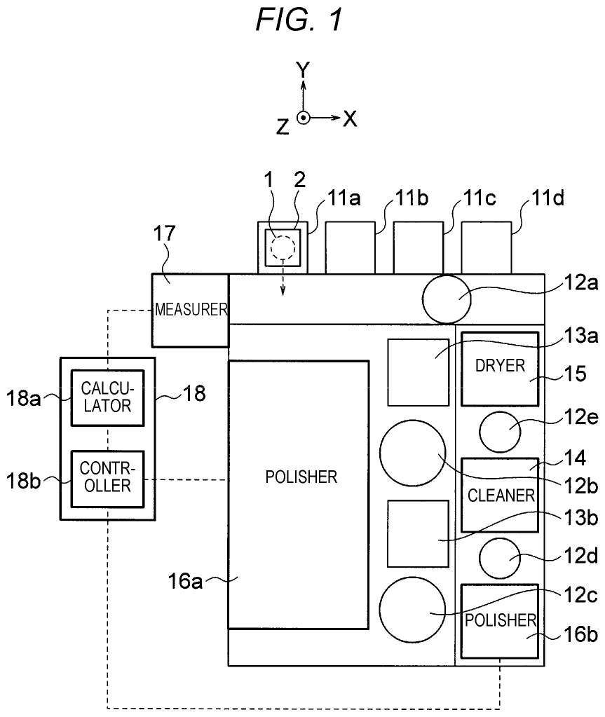

Hereinafter, at least one embodiment of the present disclosure will be described with reference to the drawings. In FIGS. 1 to 7D, identical components are denoted with the same reference numerals and signs and will not be repeatedly elaborated.

### First Embodiment

FIG. 1 is a plan view of a polishing apparatus according to a first embodiment, illustrating a configuration thereof. The polishing apparatus in FIG. 1 is, for example, a chemical mechanical polishing (CMP) apparatus.

The polishing apparatus in FIG. 1 includes load ports 11a to 11d, conveyors 12a to 12e, substrate stations 13a and 13b, a cleaner 14, a dryer 15, polishers 16a and 16b, a measurer 17, and an information processor 18. The information processor 18 includes a calculator 18a and a controller 18b.

FIG. 1 indicates an X-direction, a Y-direction, and a Z-direction that are orthogonal to one another. In this specification, a +Z-direction refers to an upward direction, and a −Z-direction refers to a downward direction. The −Z-direction may or may not coincide with a gravitational direction.

A front-opening unified pod (FOUP) 2 is a cassette to contain a wafer 1 and is mounted on each of the load ports 11a to 11d. When the wafer 1 is introduced into a casing of the polishing apparatus, the FOUP 2 is mounted on one of the load ports 11a to 11d, and the wafer 1 in the FOUP 2 is introduced into the casing of the polishing apparatus. When the wafer 1 is conveyed out of the casing of the polishing apparatus, the wafer 1 in the casing of the polishing apparatus is conveyed into the FOUP 2 on one of the load ports 11a to 11d.

The conveyors 12a to 12e convey the wafer 1 in the casing of the polishing apparatus. The wafer 1 is temporarily mounted on the substrate stations 13a and 13b in the casing of the polishing apparatus. The cleaner 14 cleans the wafer 1 polished by the polishers 16a and 16b. The dryer 15 dries the wafer 1 cleaned by the cleaner 14.

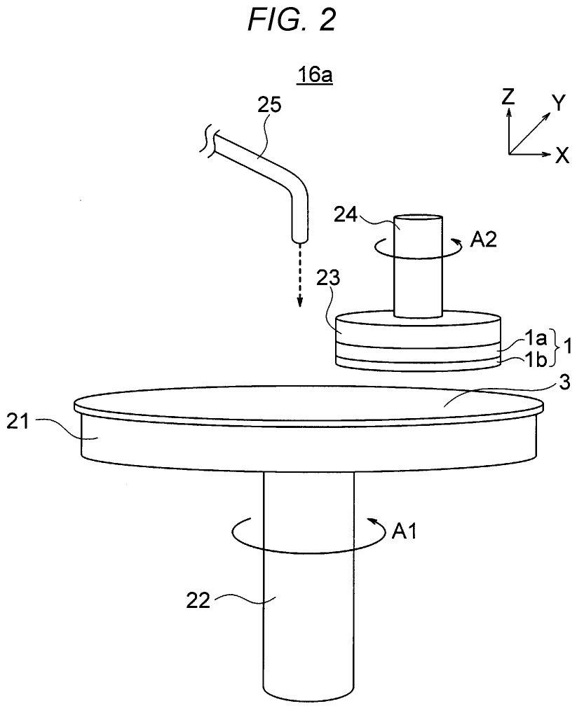

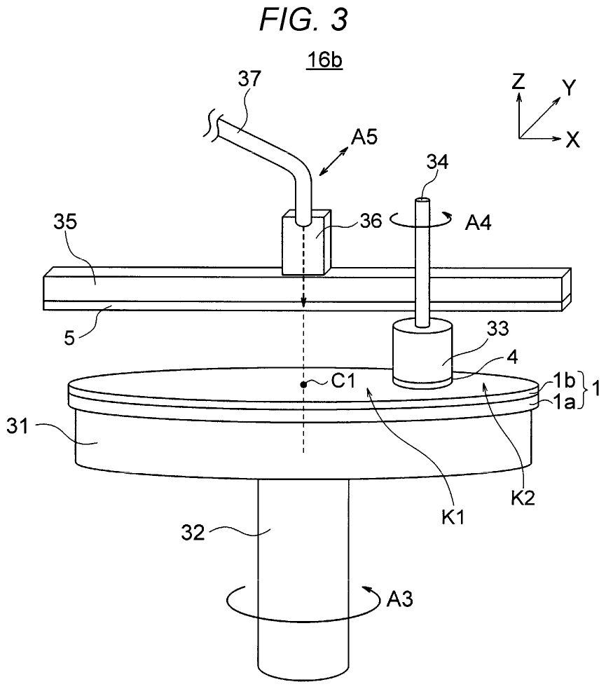

The polishers 16a and 16b polish the wafer 1 introduced into the casing of the polishing apparatus. The polisher 16a will be described in detail with reference to FIG. 2 later. The polisher 16b will be described in detail with reference to FIG. 3 later. The wafer 1 according to at least one embodiment includes, for example, a substrate 1a and a film 1b formed on a surface of the substrate 1a (see FIGS. 2 and 3). In at least one embodiment, the entire film 1b is polished by the polisher 16a, and a film thickness of the film 1b is formed as desired by the polisher 16b.

The measurer 17 measures data concerning the wafer 1 and outputs the measured data to the information processor 18. The measurer 17 according to this embodiment measures data concerning the substrate 1a or the film 1b, such as the film thickness of the film 1b.

The information processor 18 performs various kinds of information processing. Examples of the information processor 18 include a processor, an electric circuit, and a computer.

The calculator 18a receives the data measured by the measurer 17 and performs calculation concerning the received data. The calculator 18a according to at least one embodiment determines a polishing condition for polishing the film 1b based on the received data. For example, the calculator 18a determines a corrective polishing condition for correcting the film thickness of the film 1b by polishing based on the film thickness of the film 1b.

The controller 18b controls operation of the polishing apparatus. The controller 18b according to at least one embodiment controls polishing of the film 1b by the polishers 16a and 16b based on the polishing condition determined by the calculator 18a. For example, the controller 18b controls operation of the polisher 16b in correcting the film thickness of the film 1b based on the above-mentioned corrective polishing condition.

It is noted that although the measurer 17 and the information processor 18 are disposed outside of the casing of the polishing apparatus in FIG. 1, the measurer 17 and the information processor 18 may be disposed inside of the casing of the polishing apparatus.

FIG. 2 is a perspective view of the polisher 16a according to the first embodiment, illustrating a configuration thereof.

The polisher 16a includes a polishing table 21, a rotary shaft 22, a polishing head 23, a drive arm 24, and a slurry supplier 25. The polishing table 21 is an example of the third pad holder. The polishing head 23 is an example of the second substrate holder. The drive arm 24 is an example of the third driver.

The polishing table 21 is capable of holding a polishing pad (e.g., polishing cloth) 3 for polishing the wafer 1. In this embodiment, the polishing pad 3 has a circular plan-view shape (in an X-Y plane), and the polishing table 21 also has a circular plan-view shape. An area of an upper surface of the polishing pad 3 may be larger or smaller than or equal to an area of an upper surface of the polishing table 21. In FIG. 2, the upper surface of the polishing pad 3 has a slightly larger area than the upper surface of the polishing table 21. The polishing pad 3 is an example of the third pad.

The rotary shaft 22 is attached to the polishing table 21 and rotates the polishing pad 3 attached to the polishing table 21. An arrow A1 indicates how the rotary shaft 22 rotates the polishing table 21 and the polishing pad 3. Operation of the rotary shaft 22 is controlled by the above-described controller 18b.

The polishing head 23 is capable of holding the wafer 1 facedown. The wafer 1 according to at least one embodiment includes, for example, the substrate 1a and the film 1b formed on a surface (a lower surface in this case) of the substrate 1a. The substrate 1a may be, for example, a semiconductor substrate such as a silicon substrate. The film 1b is a film to be polished by the polishing apparatus. In the polisher 16a in FIG. 2, a surface (a lower surface in this case) of the film 1b is polished by the polishing pad 3. Thus, the lower surface of the film 1b is a surface to be polished. In at least one embodiment, the wafer 1 has a circular plan-view shape, and the polishing head 23 also has a circular plan-view shape. An area of a lower surface of the wafer 1 maybe larger or smaller than or equal to an area of a lower surface of the polishing head 23. In FIG. 2, the lower surface of the wafer 1 has substantially the same area as the lower surface of the polishing head 23.

The drive arm 24 is attached to the polishing head 23 and moves and rotates the wafer 1 attached to the polishing head 23. An arrow A2 indicates how the drive arm 24 rotates the polishing head 23 and the wafer 1. In at least one embodiment, a rotation direction indicated by the arrow A2 is identical with a rotation direction indicated by the arrow A1. Operation of the drive arm 24 is controlled by the above-described controller 18b.

The slurry supplier 25 supplies slurry (polishing agent) to the polishing pad 3 attached to the polishing table 21. Specifically, the slurry supplier 25 discharges liquid slurry onto a surface (the upper surface in this case) of the polishing pad 3. Operation of the slurry supplier 25 is controlled by the above-described controller 18b.

When the wafer 1 is polished by the polishing pad 3, the slurry supplier 25 supplies slurry onto the upper surface of the polishing pad 3, and the rotary shaft 22 rotates the polishing pad 3. Moreover, the drive arm 24 brings the lower surface of the wafer 1 (the film 1b) into contact with the upper surface of the polishing pad 3 and causes the wafer 1 to rotate on the upper surface of the polishing pad 3. Thus, the lower surface of the wafer 1 is polished by the polishing pad 3.

In at least one embodiment, a diameter of the polishing pad 3 is longer than a diameter of the wafer 1. Consequently, the entire lower surface of the film 1b can come into contact with the upper surface of the polishing pad 3, and the entire lower surface of the film 1b can be polished by the polishing pad 3. In at least one embodiment, the area of the upper surface of the polishing pad 3 is slightly larger than the area of the upper surface of the polishing table 21, and the area of the lower surface of the wafer 1 is substantially the same as the area of the lower surface of the polishing head 23. Therefore, a diameter of the polishing table 21 is longer than a diameter of the polishing head 23.

The slurry supplied to the upper surface of the polishing pad 3 is spread over the entire upper surface of the polishing pad 3 by rotation of the polishing pad 3. However, because a state of the upper surface of the polishing pad 3 changes, for example, an amount of supplied slurry may vary at different in-plane positions of the polishing pad 3. As a result, the film thickness of the film 1b may deviate at different in-plane positions of the film 1b. In view of this, in at least one embodiment, the film thickness of the film 1b is corrected by the polisher 16b so as to reduce deviation in the film thickness of the film 1b.

FIG. 3 is a perspective view of the polisher 16b according to the first embodiment, illustrating a configuration thereof.

The polisher 16b includes a polishing table 31, a rotary shaft 32, a polishing head 33, a drive arm 34, a polishing head 35, a drive arm 36, and a slurry supplier 37. The polishing table 31 is an example of the first substrate holder. The polishing head 33 is an example of the second pad holder. The drive arm 34 is an example of the second driver. The polishing head 35 is an example of the first pad holder. The drive arm 36 is an example of the first driver.

The polishing table 31 is capable of holding the wafer 1 faceup. The wafer 1 illustrated in FIG. 3 is the same as the wafer 1 illustrated in FIG. 2 and includes the substrate 1a and the film 1b formed on a surface (an upper surface in this case) of the substrate 1a. In the polisher 16b in FIG. 3, a surface (an upper surface in this case) of the film 1b is polished by polishing pads 4 and 5, described later. Thus, the upper surface of the film 1b is a surface to be polished. In at least one embodiment, the wafer 1 has a circular plan-view shape, and the polishing table 31 also has a circular plan-view shape. An area of the upper surface of the wafer 1 may be larger or smaller than or equal to an area of the upper surface of the polishing table 31. In FIG. 3, the upper surface of the wafer 1 has a slightly larger area than the upper surface of the polishing table 31.

The rotary shaft 32 is attached to the polishing table 31 and rotates the wafer 1 attached to the polishing table 31. An arrow A3 indicates how the rotary shaft 32 rotates the polishing table 31 and the wafer 1. Operation of the rotary shaft 32 is controlled by the above-described controller 18b.

The polishing head 33 is capable of holding the polishing pad 4 for polishing the wafer 1. In at least one embodiment, the polishing pad 4 has a circular plan-view shape, and the polishing head 33 also has a circular plan-view shape. An area of a lower surface of the polishing pad 4 maybe larger or smaller than or equal to an area of a lower surface of the polishing head 33. In FIG. 3, the lower surface of the polishing pad 4 has substantially the same area as the lower surface of the polishing head 33. The polishing pad 4 is an example of the second pad.

The drive arm 34 is attached to the polishing head 33 and moves and rotates the polishing pad 4 attached to the polishing head 33. An arrow A4 indicates how the drive arm 34 rotates the polishing head 33 and the polishing pad 4. In at least one embodiment, a rotation direction indicated by the arrow A4 is identical with a rotation direction indicated by the arrow A3. Operation of the drive arm 34 is controlled by the above-described controller 18b.

The polishing head 35 is capable of holding the polishing pad 5 for polishing the wafer 1. In at least one embodiment, the polishing pad 5 has a linear plan-view shape, and the polishing head 35 may also have a linear plan-view shape. Specifically, the polishing pad 5 and the polishing head 35 according to at least one embodiment have rectangular plan-view shapes. An area of a lower surface of the polishing pad 5 may be larger or smaller than or equal to an area of a lower surface of the polishing head 35. In FIG. 3, the lower surface of the polishing pad 5 has substantially the same area as the lower surface of the polishing head 35. The polishing pad 5 is an example of the first pad.

The drive arm 36 is attached to the polishing head 35 and moves the polishing pad 5 attached to the polishing head 35. The drive arm 36 according to at least one embodiment does not rotate the polishing pad 5 on the upper surface of the wafer 1 but translates the polishing pad 5 on the upper surface of the wafer 1. An arrow A5 indicates how the drive arm 36 translates the polishing head 35 and the polishing pad 5, and specifically indicates how the drive arm 36 reciprocates (swings) the polishing head 35 and polishing pad 5. In FIG. 3, the arrow A5 indicates ±Y-directions, and the polishing head 35 and the polishing pad 5 translate in the ±Y directions. Operation of the drive arm 36 is controlled by the above-described controller 18b.

The slurry supplier 37 supplies slurry to the wafer 1 attached to the polishing table 31. Specifically, the slurry supplier 37 discharges liquid slurry onto a surface (the upper surface in this case) of the wafer 1. Operation of the slurry supplier 37 is controlled by the above-described controller 18b.

When the wafer 1 is polished by the polishing pad 4, the slurry supplier 37 supplies slurry to the upper surface of the wafer 1 (the film 1b), and the rotary shaft 32 rotates the wafer 1. Further, the drive arm 34 brings the lower surface of the polishing pad 4 into contact with the upper surface of the wafer 1 and rotates the polishing pad 4 on the upper surface of the wafer 1. Thus, the upper surface of the wafer 1 is polished by the polishing pad 4.

In at least one embodiment, a diameter of the polishing pad 4 is shorter than the diameter of the wafer 1. Consequently, the entire lower surface of the polishing pad 4 can be brought into contact with the film 1b so that the film 1b can be partly (locally) polished by the polishing pad 4. Moreover, in at least one embodiment, the polishing pad 4 is moved by the drive arm 34 so as to change a contact position of the polishing pad 4 with the wafer 1. Thus, various portions of the film 1b can be sequentially polished by the polishing pad 4 so as to reduce deviation in the film thickness of the film 1b. That is, the film thickness of the film 1b can be corrected. In at least one embodiment, the upper surface of the wafer 1 has a slightly larger area than the upper surface of the polishing table 31, and the lower surface of the polishing pad 4 has substantially the same area as the lower surface of the polishing head 33. Therefore, a diameter of the polishing head 33 is shorter than a diameter of the polishing table 31.

When the wafer 1 is polished by the polishing pad 5, the slurry supplier 37 also supplies slurry to the upper surface of the wafer 1, and the rotary shaft 32 rotates the wafer 1. Further, the drive arm 36 brings the lower surface of the polishing pad 5 into contact with the upper surface of the wafer 1 and translates the polishing pad 5 on the upper surface of the wafer 1. Thus, the upper surface of the wafer 1 is polished by the polishing pad 5.

In FIG. 3, a longer side of the polishing pad 5 is parallel to the X-direction, and a shorter side of the polishing pad 5 is parallel to the Y-direction. In at least one embodiment, a length of the polishing pad 5, specifically, a length of the longer side of the polishing pad 5 having a rectangular plan-view shape, is longer than the diameter of the wafer 1. Further, a length of the shorter side of the polishing pad 5 having the rectangular plan-view shape is shorter than the diameter of the wafer 1. Consequently, the polishing pad 5 is translated on the upper surface of the wafer 1 by the drive arm 36 so that various portions of the film 1b can be sequentially polished by the polishing pad 5, and that the entire upper surface of the film 1b can be scanned and polished by the polishing pad 5. As a result, in a similar manner to the case of using the polishing pad 4, deviation in the film thickness of the film 1b can be reduced by the polishing pad 5. That is, the film thickness of the film 1b can be corrected by the polishing pad 5. In at least one embodiment, the upper surface of the wafer 1 has a slightly larger area than the upper surface of the polishing table 31, and the lower surface of the polishing pad 5 has substantially the same area as the lower surface of the polishing head 35. Therefore, a length of the polishing head 35, specifically, a length of a longer side of the polishing head 35 having a rectangular plan-view shape is longer than the diameter of the polishing table 31.

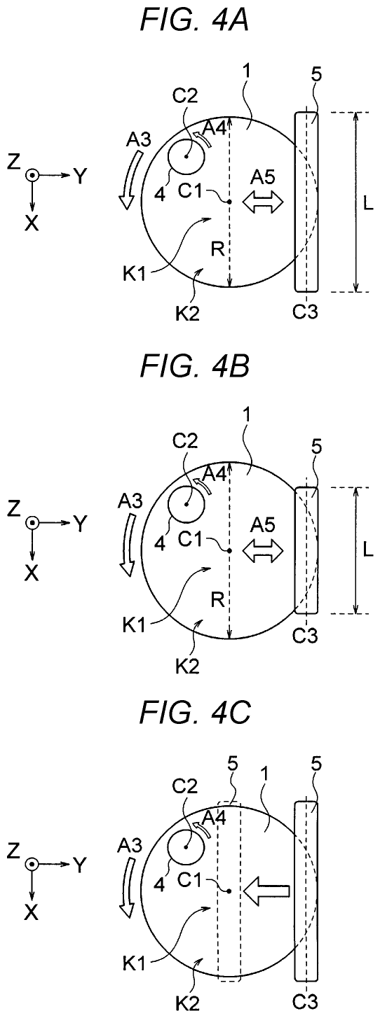

Next, referring to FIGS. 4A to 4C, a function of the polishing pad 4 and a function of the polishing pad 5 will be described in more detail.

FIGS. 4A to 4C are plan views illustrating the polisher 16b according to the first embodiment more specifically.

FIG. 4A illustrates the wafer 1, the polishing pad 4, and the polishing pad 5 in the polisher 16b according to at least one embodiment. FIG. 4A also illustrates a center axis C1 of the wafer 1, a center axis C2 of the polishing pad 4, a center plane C3 of the polishing pad 5, a diameter R of the wafer 1, and a length L of the polishing pad 5. The center axis C1 of the wafer 1 passes through a center point of a circle, which is the plan-view shape of the wafer 1. The center axis C2 of the polishing pad 4 passes through a center point of a circle, which is the plan-view shape of the polishing pad 4. The center plane C3 of the polishing pad 5 passes through a center line of a rectangle, which is the plan-view shape of the polishing pad 5, and the center line is parallel to two longer sides of the rectangle. FIG. 4A further illustrates a center portion K1 and an outer-peripheral portion K2 of the wafer 1 (see FIG. 3 as well).

When the wafer 1 is polished by the polishing pad 4, the polisher 16b rotates the wafer 1 and the polishing pad 4 as indicated by the arrows A3 and A4. Thus, a contact position of the wafer 1 with the polishing pad 4 can be changed in a circumferential direction of the wafer 1 during polishing. At this time, in the center portion K1 of the wafer 1, each point in the upper surface of the wafer 1 stays in contact with the polishing pad 4 for a long time. Meanwhile, in the outer-peripheral portion K2 of the wafer 1, each point in the upper surface of the wafer 1 is in contact with the polishing pad 4 for only a short time. Consequently, when the film thickness of the film 1b is corrected solely by the polishing pad 4, it takes a long time to correct the film thickness of the film 1b in the outer-peripheral portion K2. This may degrade correction efficiency.

When the wafer 1 is polished by the polishing pad 5, the polisher 16b rotates the wafer 1 as indicated by the arrow A3 and translates the polishing pad 5 as indicated by the arrow A5. Thus, a contact position of the wafer 1 with the polishing pad 5 can be changed in the ±Y-directions during polishing. At this time, in both of the center portion K1 and the outer-peripheral portion K2 of the wafer 1, each point in the upper surface of the wafer 1 stays in contact with the polishing pad 5 for a long time. Consequently, according to at least one embodiment, the film thickness of the film 1b is corrected by the polishing pad 5 so that the film thickness of the film 1b in the center portion K1 and the outer-peripheral portion K2 can be corrected in a short time. This can improve correction efficiency. Moreover, in use of the polishing pad 5, slurry is less likely to flow down from the upper surface of the wafer 1 than in use of the polishing pad 4. Therefore, use of the polishing pad 5 can reduce waste of the slurry.

In at least one embodiment, the polisher 16b includes both of the polishing head 33 for the polishing pad 4 and the polishing head 35 for the polishing pad 5. However, the polisher 16b may include only one of the polishing heads 33 and 35. For example, when the polisher 16b includes the polishing head 35 alone, the film thickness of the film 1b in the center portion K1 and the outer-peripheral portion K2 can be corrected in a shorter time than without the polishing heads 33 and 35. However, because the polishing pad 4 can polish the wafer 1 while restricting a polishing location more locally than the polishing pad 5, the polisher 16b preferably includes both of the polishing heads 33 and 35. With this configuration, the film thickness of the film 1b can be corrected by the polishing pad 4 and the polishing pad 5 at high speed and with high accuracy. Therefore, the polisher 16b according to at least one embodiment has a multi-head configuration including the polishing head 33 and the polishing head 35.

FIG. 4B illustrates the wafer 1, the polishing pad 4, and the polishing pad 5 in the polisher 16b according to a modification of this embodiment. Although the length L of the polishing pad 5 in FIG. 4A is longer than the diameter R of the wafer 1, the length L of the polishing pad 5 in FIG. 4B is shorter than the diameter R of the wafer 1. The length L of the polishing pad 5 may be longer than the diameter R of the wafer 1 as illustrated in FIG. 4A and may be shorter than the diameter R of the wafer 1 as illustrated in FIG. 4B. Preferably, however, the length L of the polishing pad 5 is longer than the diameter R of the wafer 1 as illustrated in FIG. 4A. The reason will be described with reference to FIG. 4C.

In a similar manner to FIG. 4A, FIG. 4C illustrates the wafer 1, the polishing pad 4, and the polishing pad 5 in the polisher 16b according to at least one embodiment. In FIG. 4C, the length L of the polishing pad 5 is longer than the diameter R of the wafer 1.

In FIG. 4C, a state where the polishing pad 5 is located above the center axis C1 of the wafer 1 is indicated by a dotted line. In this case, the polishing pad 5 is in contact with the upper surface of the wafer 1 from an end portion of the wafer 1 in a +X-direction to an end portion of the wafer 1 in a −X-direction. The reason is that the length L of the polishing pad 5 is longer than the diameter R of the wafer 1. When the length L is shorter than the diameter R, the polishing pad 5 is not in contact with the upper surface of the wafer 1 at an end portion of the wafer 1 in the +X-direction and at an end portion of the wafer 1 in the −X-direction. In this case, when the polishing pad 5 is at a position indicated by the dotted line, the end portions of the wafer 1 in the ±X-directions are not polished by the polishing pad 5. This may result in inadequate correction. When the length L is longer than the diameter R, the end portions of the wafer 1 in the ±X-directions can be prevented from being left unpolished so that the entire upper surface of the wafer 1 can be fully scanned and polished by the polishing pad 5 without failure.

Next, referring back to FIG. 1, an example of a polishing method of the wafer 1 by the polishing apparatus according to at least one embodiment will be described. In this description, reference numerals and signs indicated in FIGS. 2 to 4C will be used as necessary.

First, the FOUP 2 is placed on one of the load ports 11a to 11d, and the wafer 1 is taken out of the FOUP 2. Next, the wafer 1 taken out is introduced into the polisher 16a via the conveyor 12a, the substrate station 13a, and the conveyor 12b, and the polishing pad 3 in the polisher 16a polishes the entire film 1b.

Next, the wafer 1 after being polished is conveyed into the cleaner 14 via the conveyor 12b, and the wafer 1 is cleaned in the cleaner 14. Next, the wafer 1 after being cleaned is conveyed into the dryer 15 via the conveyor 12e, and the wafer 1 is dried in the dryer 15.

Next, the wafer 1 after being dried is conveyed into the measurer 17 via the conveyor 12a, and data concerning the wafer 1 is measured in the measurer 17. The measurer 17 according to at least one embodiment measures data concerning a surface state of the wafer 1, such as a film thickness of the film 1b. Thereafter, the wafer 1 is accommodated in the above-described FOUP 2.

Next, the information processor 18 determines whether there is need to correct the film thickness of the film 1b, and when film thickness correction is needed, the wafer 1 is taken out of the FOUP 2 again. It is noted that while the information processor 18 is making this determination, the wafer 1 may remain on standby in the measurer 17 or other places instead of being accommodated in the FOUP 2.

Next, the wafer 1 taken out is conveyed into the polisher 16b via the conveyor 12a, the substrate station 13a, the conveyor 12b, the substrate station 13b, and the conveyor 12c, and the polishing pads 4 and 5 in the polisher 16b correct the film thickness of the film 1b by polishing. At this time, the calculator 18a determines a corrective polishing condition for correcting the film thickness of the film 1b by polishing based on the film thickness of the film 1b measured by the measurer 17, and the controller 18b controls operation of the polishing pads 4 and 5 in correcting the film thickness of the film 1b based on the corrective polishing condition. For example, when there is need to reduce the film thickness of the film 1b in the center portion K1, the film 1b in the center portion K1 is polished by the polishing pad 4, and when there is need to reduce the film thickness of the film 1b in the outer-peripheral portion K2, the film 1b in the outer-peripheral portion K2 is polished by the polishing pad 5. It is noted that the polishing pad 4 and the polishing pad 5 may polish the wafer 1 simultaneously or in turn.

Examples of the corrective polishing condition include a load, a rotation speed, and a polishing position of the polishing pad 4 in polishing the film 1b, and a load, a translation speed, and a swinging distance of the polishing pad 5 in polishing the film 1b. The loads of the polishing pads 4 and 5 are loads respectively applied to the polishing pads 4 and 5 by the drive arms 34 and 36 via the polishing heads 33 and 35. The rotation speed of the polishing pad 4 is a speed (such as an RPM value) at which the polishing pad 4 rotates on the film 1b. The translation speed of the polishing pad 5 is a speed at which the polishing pad 5 translates on the film 1b. The polishing position of the polishing pad 4 is a position where the polishing pad 4 polishes the film 1b. The swinging distance of the polishing pad 5 is a distance of translation of the polishing pad 5 on the film 1b, for example, a value twice longer than an amplitude of the translation.

Next, the wafer 1 after being polished is conveyed into the cleaner 14 via the conveyor 12d, and the wafer 1 is cleaned in the cleaner 14. Next, the wafer 1 after being cleaned is conveyed into the dryer 15 via the conveyor 12e, and the wafer 1 is dried in the dryer 15.

Next, the wafer 1 after being dried is conveyed into the measurer 17 via the conveyor 12a, and data concerning the wafer 1 is measured in the measurer 17 again. Thereafter, the wafer 1 is accommodated in the above-described FOUP 2.

Next, the information processor 18 determines whether there is need to correct the film thickness of the film 1b of the wafer 1 again, and when film thickness correction is needed, the wafer 1 is taken out of the FOUP 2 again. The wafer 1 taken out is polished in the polisher 16b again.

In this method, polishing of the wafer 1 by the polisher 16b is repeated until the information processor 18 determines that it is no longer necessary to correct the film thickness of the film 1b of the wafer 1. In this manner, the polishing apparatus according to at least one embodiment polishes the wafer 1.

It is noted that instead of being disposed at the position illustrated in FIG. 1, the measurer 17 may be disposed in at least one of an inside of the polisher 16a, the vicinity of the polisher 16a, an inside of the polisher 16b, and the vicinity of the polisher 16b. In this case, the measurer 17 may measure data concerning the wafer 1 being polished in the polisher 16a or may measure data concerning the wafer 1 being polished in the polisher 16b. In this manner, the measurer 17 according to at least one embodiment may measure data concerning the wafer 1 after being polished or may measure data concerning the wafer 1 being polished.

As described above, the polishing apparatus according to at least one embodiment causes the polishing pad 5 to translate on the surface of the wafer 1 (i.e., the film 1b) so as to polish the wafer 1. Thus, according to at least one embodiment, the film thickness of the film 1b can be appropriately corrected by the polishing pad 5. For example, the film thickness of the film 1b in the outer-peripheral portion K2 of the wafer 1 can be corrected by the polishing pad 5 at high speed.

Moreover, the polishing apparatus according to at least one embodiment causes the polishing pad 4 to rotate on the surface of the wafer 1 (i.e., the film 1b) so as to polish the wafer 1. Thus, according to at least one embodiment, the film thickness of the film 1b can be more appropriately corrected by the polishing pad 4. For example, the film thickness of the film 1b can be corrected by the polishing pad 4 with high accuracy.

The polisher 16b in polishing apparatuses according to second to fourth embodiments will now be described. In describing the second to fourth embodiments, details in common with the first embodiment will be omitted unless occasion demands, and differences from the first embodiment will be focused.

### Second Embodiment

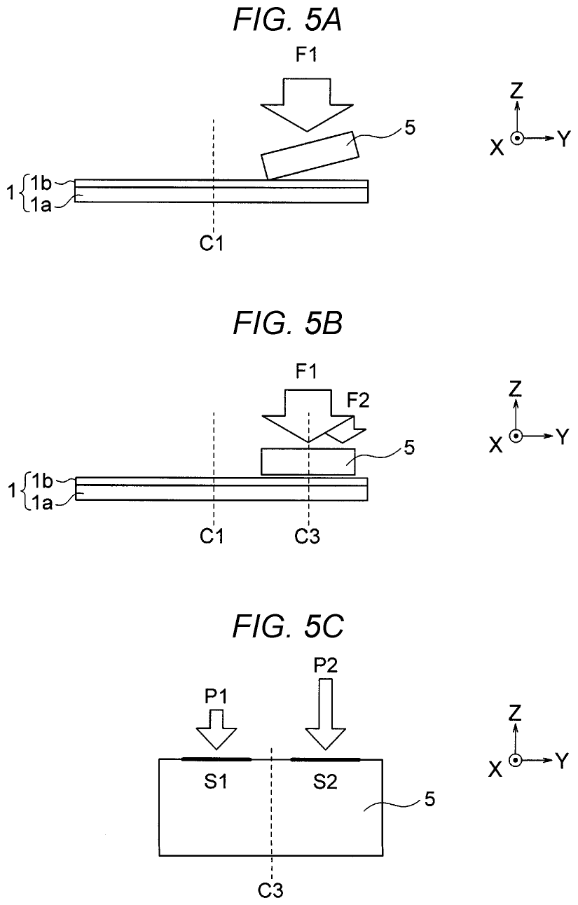

FIGS. 5A to 5C are cross-sectional views illustrating a configuration and operation of the polisher 16b according to the second embodiment.

FIG. 5A illustrates a load Fl that the polishing head 35 pressed by the drive arm 36 applies to the polishing pad 5. Since frictional force is exerted between the wafer 1 and the polishing pad 5, the polishing pad 5 may be inclined as illustrated in FIG. 5A. In such a case, a contact area between the wafer 1 and the polishing pad 5 may decrease to hinder full polishing of the wafer 1. In view of this, a mechanism to prevent the polishing pad 5 from being inclined is desirably provided for the polisher 16b.

FIG. 5B illustrates the load F1 and a load F2 that the polishing head 35 pressed by the drive arm 36 applies to the polishing pad 5. A magnitude and a distribution of the load F1 is symmetrical to the center plane C3 of the polishing pad 5. Meanwhile, a magnitude and a distribution of the load F2 is asymmetrical to the center plane C3 of the polishing pad 5. The polishing head 35 according to at least one embodiment applies the load F1 and the load F2 to the polishing pad 5 so that asymmetrical load with respect to the center plane C3 of the polishing pad 5 can be applied to the polishing pad 5. This can prevent the polishing pad 5 from being inclined.

As illustrated in FIG. 5A, generally, the polishing pad 5 is more likely to be raised on a side far from the center axis C1 of the wafer 1 than on a side close to the center axis C1 of the wafer 1. In view of this, as illustrated in FIG. 5B, for example, the load F2 according to at least one embodiment is set at such a value that a larger load is applied to the far side from the center axis C1 of the wafer 1. This can effectively prevent the polishing pad 5 from being inclined.

FIG. 5C is a cross-sectional view illustrating such loads F1 and F2 from a viewpoint of pressures P1 and P2. FIG. 5C illustrates regions S1 and S2 of the upper surface of the polishing pad 5 and the pressures P1 and P2 respectively applied to the regions S1 and S2. The region S2 is located at a position further from the center axis C1 of the wafer 1 than the region S1 is. Specifically, the region S2 is located in the +Y-direction of the region S1. The pressure P2 is higher than the pressure P1. The regions S1 and S2 are respectively examples of the first and second regions. The pressures P1 and P2 are respectively examples of the first and second pressures.

As described above, as illustrated in FIG. 5B, for example, the load F2 according to at least one embodiment is set at such a value that a larger load is applied to the far side from the center axis C1 of the wafer 1. Consequently, as illustrated in FIG. 5C, the pressure P2 applied to the region S2 is higher than the pressure P1 applied to the region S1. This can effectively prevent the polishing pad 5 from being inclined.

It is noted that in at least one embodiment, the above-described loads F1 and F2 may be applied to the polishing pad 4. In this case, a magnitude and a distribution of the load F1 is symmetrical to the center axis C2 of the polishing pad 4, and a magnitude and a distribution of the load F2 is asymmetrical to the center axis C2 of the polishing pad 4. Thus, the pressure P2 applied to the region S2 on the polishing pad 4 can be made higher than the pressure P1 applied to the region S1 on the polishing pad 4 so as to prevent the polishing pad 4 from being inclined.

### Third Embodiment

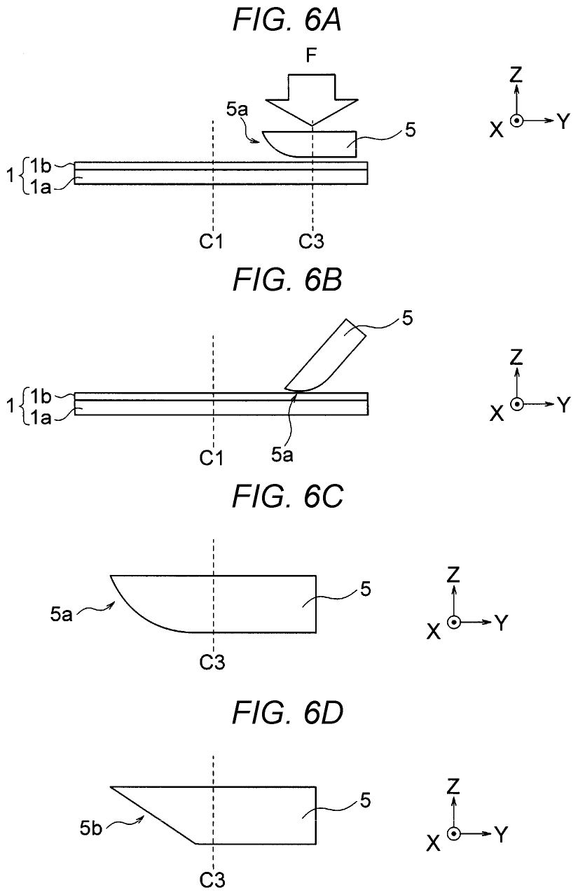

FIGS. 6A to 6D are cross-sectional views illustrating a configuration and operation of the polisher 16b according to the third embodiment.

As illustrated in FIG. 6A, the polishing pad 5 according to at least one embodiment has a curved side surface 5a on the center axis C1 side of the wafer 1. For example, when the polishing pad 5 has a rectangular plan-view shape, the polishing pad 5 has an upper surface, a lower surface, and four side surfaces. Among the four side surface, at least the side surface 5a on the center axis C1 side is curved. In FIG. 6A, the side surface 5a of the polishing pad 5 is a side surface of the polishing pad 5 in the Y-direction. The side surface 5a according to at least one embodiment is rounded and has a curved shape along a Y-Z plane in FIG. 6A, for example. Moreover, the side surface 5a according to at least one embodiment does not facet an opposite side of the wafer 1 but faces the wafer 1, that is, the side surface 5a does not face diagonally upward but faces diagonally downward.

FIG. 6A further illustrates a load F that the polishing head 35 pressed by the drive arm 36 applies to the polishing pad 5. When a magnitude and a distribution of the load F is symmetrical to the center plane C3 of the polishing pad 5, the polishing pad 5 may be inclined as illustrated in FIG. 6B in some cases. For the above-described reason, the polishing pad 5 illustrated in FIG. 6B is raised on a far side from the center axis C1 of the wafer 1.

In this case, in the second embodiment, a contact area between the wafer 1 and the polishing pad 5 may notably decrease (see FIG. 5A). According to the third embodiment, the side surface 5a of the polishing pad 5 is curved in such a manner that even when the polishing pad 5 is inclined, the contact area between the wafer 1 and the polishing pad 5 can be prevented from notably decreasing (see FIG. 6B). Consequently, even when the polishing pad 5 is inclined, the wafer 1 can be fully polished.

FIG. 6C is an enlarged cross-sectional view of the polishing pad 5 according to at least one embodiment. FIG. 6D is an enlarged cross-sectional view of the polishing pad 5 according to a modification of at least one embodiment. The polishing pad 5 according to this modification has an inclined plane side surface 5b on the center axis C1 side of the wafer 1. According to this modification, providing the side surface 5b for the polishing pad 5 can produce substantially the same effect as providing the side surface 5a for the polishing pad 5. It is noted that although both of the side surfaces 5a and 5b are inclined, the side surface 5a is curved, and the side surface 5b is plane.

It is noted that according to at least one embodiment, a side surface of the polishing pad 4 may be substantially the same curved surface as the side surface 5a or substantially the same inclined plane surface as the side surface 5b. However, because the polishing pad 4 is used in a rotating state, the entire side surface of the polishing pad 4 is desirably substantially the same curved surface as the side surface 5a or substantially the same inclined plane surface as the side surface 5b. Consequently, even when the polishing pad 4 is inclined, the wafer 1 can be fully polished.

### Fourth Embodiment

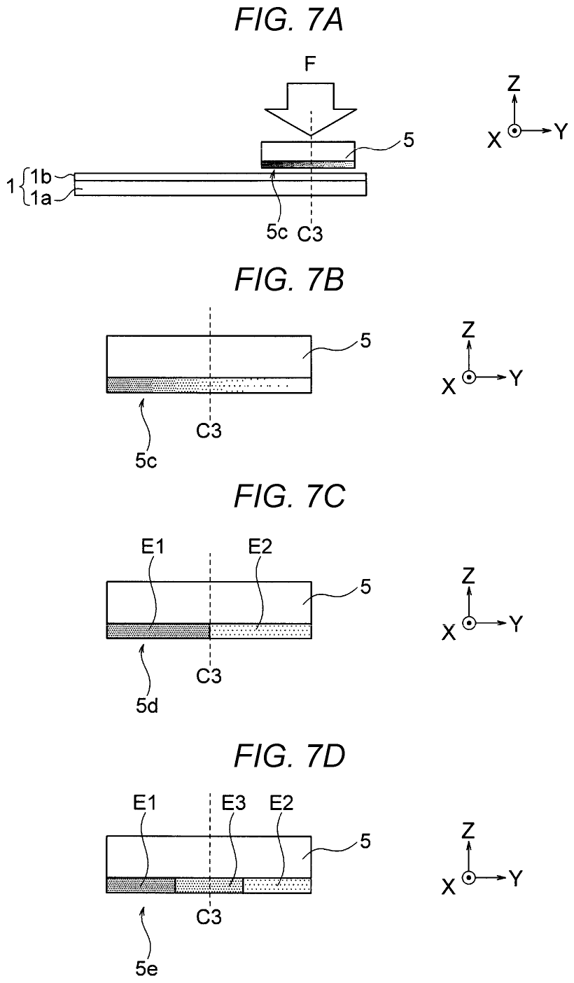

FIGS. 7A to 7D are cross-sectional views illustrating a configuration and operation of the polisher 16b according to the fourth embodiment.

FIG. 7A illustrates a surface portion 5c, which is a portion in the vicinity of a surface (the lower surface) of the polishing pad 5. A density of dots in the surface portion 5c indicates a state of friction coefficients in the surface portion 5c. Specifically, a region with a high density of dots has high friction coefficients, and a region with a low density of dots has low friction coefficients. The friction coefficients in the surface portion 5c according to at least one embodiment are not uniform but vary in different regions in the surface portion 5c. The friction coefficients in this case correspond to kinetic friction coefficients.

FIG. 7B is an enlarged cross-sectional view of the polishing pad 5 according to at least one embodiment. As illustrated in FIG. 7B, the surface portion 5c of the polishing pad 5 according to at least one embodiment has friction coefficients of an asymmetrical distribution with respect to the center plane C3 of the polishing pad 5. Specifically, a friction coefficient at a location in the surface portion 5c is lower as a Y-coordinate of the location becomes larger. Thus, in a similar manner to the case of applying a large load to the far side from the center axis C1 of the wafer 1 in the second embodiment, the polishing pad 5 can be effectively prevented from being inclined.

FIG. 7C is an enlarged cross-sectional view of the polishing pad 5 according to a modification of at least one embodiment. A surface portion 5d of the polishing pad 5 according to this modification also has friction coefficients of an asymmetrical distribution with respect to the center plane C3 of the polishing pad 5. Specifically, the surface portion 5d includes a portion E1 with a high friction coefficient and a portion E2 with a low friction coefficient. The portion E2 is located at a position further from the center axis C1 of the wafer 1 than the portion E1 is. Specifically, the portion E2 is located in the +Y-direction of the portion E1. The portion E1 is an example of the first portion, and the portion E2 is an example of the second portion. According to this modification, providing such a surface portion 5d in the polishing pad 5 can produce substantially the same effect as the polishing pad 5 having the surface portion 5c.

FIG. 7D is an enlarged cross-sectional view of the polishing pad 5 according to a modification of at least one embodiment. A surface portion 5e of the polishing pad 5 according to this modification also has friction coefficients of an asymmetrical distribution with respect to the center plane C3 of the polishing pad 5. Specifically, the surface portion 5e includes the portion E1 with a high friction coefficient, a portion E3 with an intermediate friction coefficient, and the portion E2 with a low friction coefficient. The portion E3 is located in the +Y-direction of the portion E1 and located in the −Y-direction of the portion E2. When the portions E1 and E3 are focused on, the portion E1 is an example of the first portion, and the portion E3 is an example of the second portion. When the portions E3 and E2 are focused on, the portion E3 is an example of the first portion, and the portion E2 is an example of the second portion. According to this modification, providing such a surface portion 5e in the polishing pad 5 can produce substantially the same effect as the polishing pad 5 having the surface portion 5c.

It is noted that the surface portion 5c illustrated in FIG. 7B can be regarded as including a large number of portions of different friction coefficients in a similar manner to the surface portion 5d including the two portions E1 and E2 and the surface portion 5e including the three portions E1 to E3. Freely selected two portions in the surface portion 5c are also examples of the first portion and the second portion. These surface portions 5c, 5d, and 5e can be produced by, for example, changing a composition and a quality of the surface of the polishing pad 5.

It is noted that in at least one embodiment, a surface (the lower surface) of the polishing pad 4 maybe provided with a surface portion similar to one of the surface portions 5c, 5d, and 5e. In this case, the surface portion of the polishing pad 4 desirably has friction coefficients of an asymmetrical distribution with respect to the center axis C2 of the polishing pad 4. For example, a friction coefficient at a location in the surface portion is desirably lower as the location is further from the center axis C2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A polishing apparatus comprising:
a first substrate holder arranged to hold a substrate coated with a film;
a first pad holder arranged to hold a first pad; and
a first driver configured to translate the first pad on a surface of the film so as to cause the first pad to polish the film.

2. The polishing apparatus according to claim 1, wherein the first pad holder has a linear shape in plan-view.

3. The polishing apparatus according to claim 1, wherein a length of a longer side of the first pad holder is longer than a diameter of the first substrate holder.

4. The polishing apparatus according to claim 1, further comprising:
a second pad holder configured to hold a second pad; and
a second driver configured to rotate the second pad on the surface of the film so as to cause the second pad to polish the film.

5. The polishing apparatus according to claim 4, wherein the second pad holder has a circular shape in plan-view.

6. The polishing apparatus according to claim 4, wherein a diameter of the second pad holder is shorter than the diameter of the first substrate holder.

7. The polishing apparatus according to claim 4, wherein the first or second pad holder is configured to apply to the first pad or the second pad an asymmetrical load with respect to a center plane or a center axis of the first pad or the second pad.

8. The polishing apparatus according to claim 4, wherein the first pad or the second pad has a curved or inclined side surface at least on a center axis side of the substrate.

9. The polishing apparatus according to claim 4, wherein a surface of the first pad or the second pad has friction coefficients of an asymmetrical distribution with respect to a center plane or a center axis of the first or second pad.

10. The polishing apparatus according to claim 1, further comprising:
a second substrate holder arranged to hold the substrate;
a third pad holder arranged to hold a third pad; and
a third driver configured to rotate the substrate on a surface of the third pad so as to cause the third pad to polish the film.

11. The polishing apparatus according to claim 10, wherein the third pad holder has a circular shape in plan-view.

12. The polishing apparatus according to claim 10, wherein a diameter of the third pad holder is longer than a diameter of the second substrate holder.

13. The polishing apparatus according to claim 10, further comprising:
a measurer configured to measure data concerning the substrate or the film during or after polishing of the film by the third pad; and
a controller configured to control polishing of the film by the first pad based on the measured data.

14. The polishing apparatus according to claim 13, wherein the data measured concerning the substrate or the film includes a film thickness of the film.

15. The polishing apparatus according to claim 13, wherein the controller is configured to control a load, a translation speed, or a swinging distance of the first pad during polishing of the film based on the measured data .

16. A polishing method comprising:
holding a substrate coated with a film by a first substrate holder;
holding a first pad by a first pad holder; and
translating the first pad on a surface of the film by a first driver so as to cause the first pad to polish the film.

17. The polishing method according to claim 16, further comprising:
holding a second pad by a second pad holder; and
rotating the second pad on a surface of the film by a second driver so as to cause the second pad to polish the film.

18. The polishing method according to claim 17, wherein the polishing by the first pad and the polishing by the second pad are simultaneously performed.

19. The polishing method according to claim 16, further comprising:
holding the substrate by a second substrate holder;
holding a third pad by a third pad holder; and
prior to the polishing of the film by the first pad, rotating the substrate on a surface of the third pad by a third driver so as to cause the third pad to polish the film.

20. The polishing method according to claim 19, further comprising:
measuring, by a measurer, data concerning the substrate or the film during or after polishing of the film by the third pad; and
controlling, by a controller, the polishing of the film by the first pad based on the measured data.
